(19) United States
(12) Patent Application Publication
(10) Pub. No.: US 2025/0110165 A1
(43) Pub. Date: Apr. 3, 2025

(54) Electrostatic Discharge Testing

(71) Applicant: APPLE INC., Cupertino, CA (US)

(72) Inventors: Shaowu Huang, Los Altos, CA (US); Jing Li Lim, Sunnyvale, CA (US); Keong W. Kam, San Jose, CA (US); Ramachandran Chundru, Cupertino, CA (US)

(21) Appl. No.: 18/806,223

(22) Filed: Aug. 15, 2024

Related U.S. Application Data
(60) Provisional application No. 63/540,951, filed on Sep. 28, 2023.

(51) Int. Cl. G01R 31/00; G02B 27/01; G06F 1/16; H01R 13/648; H05K 9/00

(52) U.S. Cl. CPC G01R 31/002; G06F 1/1656; H01R 13/6485; H05K 9/0067; G02B 27/0172; G02B 27/0176

(57) ABSTRACT

A method for electrostatic discharge testing of a head-mounted device including a housing and a headband coupled to the housing includes the steps of applying a shielding material to the head-mounted device such that the shielding material covers an outer surface of the housing and an outer surface of the headband, removing a first portion of the shielding material from a first area of the head-mounted device, applying an electrical charge to the head-mounted device, and assessing the head-mounted device for coupling paths associated with an electrostatic discharge failure.

### CROSS-REFERENCE TO RELATED APPLICATIONS

This application claims priority to U.S. Provisional Application Ser. No. 63/540,951, filed Sep. 28, 2023, the contents of which are incorporated herein by reference.

### FIELD

The present disclosure relates generally to the field of electrostatic discharge testing.

### BACKGROUND

Electrostatic discharge (ESD) is a rapid release of energy between two objects with different potential charges. The release is commonly through air and contact discharge, caused by a buildup of static electricity. The quick discharge of energy generates both voltage and current, which can have an impact on electronic devices.

### SUMMARY

One aspect of the disclosure is a method for electrostatic discharge testing of a head-mounted device including a housing and a headband coupled to the housing. The method includes the steps of applying a shielding material to the head-mounted device such that the shielding material covers an outer surface of the housing and an outer surface of the headband, removing a first portion of the shielding material from a first area of the head-mounted device, applying an electrical charge to the head-mounted device, and assessing the head-mounted device for coupling paths associated with an electrostatic discharge failure.

In some aspects, removing the first portion of the shielding material from the first area of the head-mounted device includes removing a portion of the shielding material from the housing to expose a fan opening defined by the housing.

In some aspects, removing the first portion of the shielding material from the first area of the head-mounted device includes removing a portion of the shielding material to expose a portion of the housing between a first optical module and a second optical module.

In some aspects, the method further includes determining that the electrostatic discharge failure has not been detected and in response to determining that the electrostatic discharge failure has not been detected, removing a second portion of the shielding material from a second area of the head-mounted device.

In some aspects, removing the first portion of the shielding material includes exposing a first fan opening defined by the housing on a first side of the housing and removing the second portion of the shielding material includes exposing a second fan opening defined by the housing on a second side of the housing.

In some aspects, the method further includes performing a second assessment of the head-mounted device for coupling paths associated with an electrostatic discharge failure with the first portion and the second portion of the shielding material removed from the head-mounted device.

Another aspect of the disclosure is a method for electrostatic discharge testing of a head-mounted device including a first optical module having a first display and a second optical module having a second display, the first optical module enclosed within a first housing and the second optical module enclosed within a second housing. The method includes the steps of applying a shielding material around an outer surface of the first housing and an outer surface of the second housing, removing a first portion of the shielding material from a first area of the head-mounted device, applying an electrical charge to the head-mounted device, and monitoring a component of the head-mounted device to identify an error state induced by application of the electrical charge to the head-mounted device.

In some aspects, monitoring the component of the head-mounted device includes monitoring the head-mounted device for a bit flip.

In some aspects, when the bit flip is detected, the method further includes replacing the first portion of the shielding material, removing a second portion of the shielding material from a second area of the head-mounted device, applying the electrical charge to the head-mounted device, and continuing to monitor the component of the head-mounted device with the second portion of the shielding material removed from the second area of the head-mounted device.

In some aspects, removing the first portion of the shielding material from the head-mounted device includes removing a first portion of the shielding material from the first optical module such that a first portion of a display of the first optical module is uncovered.

In some aspects, monitoring the component of the head-mounted device includes monitoring the display of the first optical module for a display failure.

In some aspects, the method further includes determining whether the display failure has occurred, and in response to determining that the display failure has occurred, replacing the first portion of the shielding material on the head-mounted device.

In some aspects, the method further includes determining whether the display failure has occurred and in response to determining that the display failure has not occurred, removing a second portion of the shielding material from the first optical module such that a second portion of the display of the first optical module is uncovered, and the second portion is larger than the first portion.

In some aspects, monitoring the display of the first optical module for the display failure includes registering an occurrence of a display anomaly.

Another aspect of the disclosure is a method for determining placement of electrostatic discharge shielding on a head-mounted device that includes a first optical module and a second optical module. The method includes the steps of applying a shielding material to an outer surface of the first optical module and an outer surface of the second optical module, removing a first portion of the shielding material from a first area of the first optical module such that a first portion of the first optical module is not covered by the shielding material, removing a second portion of the shielding material from a first area of the second optical module such that a first portion of the second optical module is not covered by the shielding material, applying an electrical charge to the head-mounted device, and determining whether a display failure is detected.

In some aspects, determining whether the display failure is detected includes assessing a display status of the first optical module and assessing a display status of the second optical module.

In some aspects, the method further includes, in response to determining that the display failure is not detected, removing a third portion of the shielding material from the first optical module such that a second portion of the first optical module is not covered by the shielding material and removing a fourth portion of the shielding material from the second optical module such that a second portion of the second optical module is not covered by the shielding material.

In some aspects, the method further includes the steps of performing a second determination of whether the display failure is detected subsequent to removing the third portion of the shielding material from the first optical module and removing the fourth portion of the shielding material from the second optical module, and, if the display failure is not detected, removing a fifth portion of the shielding material from the first optical module such that a surface of a lens area of the first optical module is not covered with the shielding material.

In some aspects, the method further includes performing one or more iterations of removing an additional portion of shielding material from the head-mounted device and determining whether the display failure is detected until the display failure is detected.

In some aspects, the display failure is detected upon occurrence of a bit flip.

### BRIEF DESCRIPTION OF THE DRAWINGS

FIG. 1 is a schematic perspective view illustration of a head-mounted device according to another implementation.

FIG. 2 is a schematic perspective view illustration of the head-mounted device of FIG. 1, with shielding material removed, according to an implementation.

FIG. 3 is a schematic exploded cross-sectional view illustration of an optical module of the head-mounted device of FIG. 1.

FIG. 4 is a schematic exploded cross-sectional view illustration of another optical module of the head-mounted device of FIG. 1.

FIG. 5 is a schematic rear-view illustration of a head-mounted device covered in a shielding material according to another implementation.

FIG. 6 is a schematic rear-view illustration of the head-mounted device of FIG. 5, with additional shielding material removed.

FIG. 7 is a schematic rear-view illustration of the head-mounted device of FIG. 5, with additional shielding material removed.

FIG. 8 is a schematic top-view illustration of the head-mounted device of FIG. 5 with shielding material covering each optical module.

FIG. 9 is a schematic underside-view illustration of the head-mounted device of FIG. 5 with shielding material covering each optical module.

FIG. 10 is a schematic top-view illustration of the head-mounted device of FIG. 5 with additional shielding material removed.

FIG. 11 is a flowchart diagram of a method for electrostatic discharge testing of a head-mounted device, according to an implementation.

FIG. 12 is a flowchart diagram of a method for electrostatic discharge testing of a head-mounted device, according to another implementation.

FIG. 13 is a flowchart diagram of a method for electrostatic discharge testing of a head-mounted device, according to another implementation.

### DETAILED DESCRIPTION

Due to the configuration of head-mounted devices, there are unique electrostatic discharge (ESD) challenges. The openings of ingress/egress vents and display screens are susceptible to electromagnetic (EM) field coupling disturbances in ESD events. The surface of the head-mounted device that faces the user (e.g., the user side that is in touch with or adjacent to the user's face and eyes) is another susceptible area to field coupling disturbances in ESD events. It is difficult to prevent soft and hard failures in these susceptible areas in both air and contact discharge testing, and in particular air discharge testing or zapping onto these susceptible areas. Additionally, the desire for a lightweight and small form factor increases the challenge to mitigate ESD events, as adding shielding and grounding components may increase the size and/or weight of the device.

Conventional shielding methods include adding more and more shielding and grounding step by step to the susceptible areas to achieve the desired system level ESD robustness. However, this process does not identify the root causes and issues that generate ESD events, and instead either relies on a separate analysis that is performed prior to formulation of a shielding design or relies on intuition. The inherent complexity of the head-mounted device, including numerous openings such as fan, vent, and lens openings, as well as optical modules, camera modules, and display modules, results in difficulty identifying the root causes of ESD failures by analysis of the device. Reliance on intuition to design shielding can, in some instances, result in overdesign of the shielding structures, thereby increasing and size and weight of a device unnecessarily.

The disclosure herein relates to methods for electrostatic discharge testing of a head-mounted device. The methods include a top-down approach to ESD debug and design techniques to quickly identify the root causes of ESD failures. The methods include removing shielding and grounding materials from the head-mounted device piece by piece and step by step while testing for ESD robustness after each piece of shielding or grounding is removed. The methods disclosed herein may be used to determine placement of electrostatic discharge shielding on a head-mounted device.

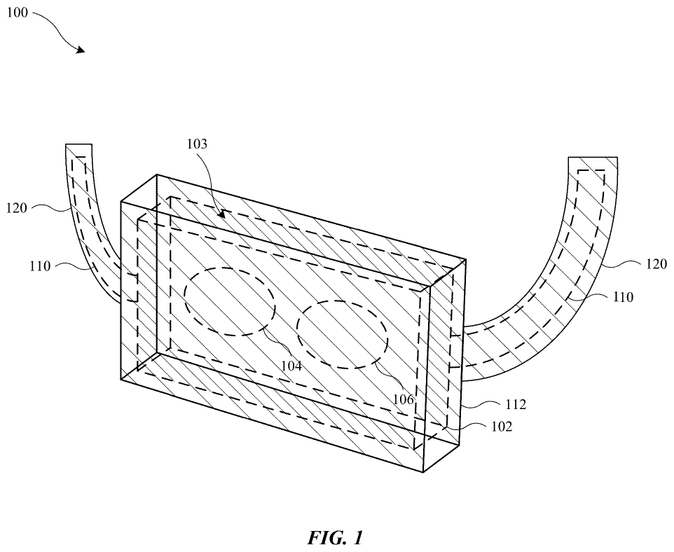

FIG. 1 is a schematic perspective view illustration of a head-mounted device 100 that includes a headband 110 for securing the head-mounted device 100 to the head of a user during use. The head-mounted device 100 is a device for delivering display output or content to a user. The head-mounted device 100 includes a housing 102, a first optical module 104 coupled to the housing 102, and a second optical module 106 coupled to the housing 102. The first optical module 104 and the second optical module 106 are configured to display content to user's eyes when the head-mounted device 100 is in use. The headband 110 is coupled to the housing 102 and, as illustrated in FIG. 1, includes a first portion extending from a first side of the housing 102 and a second portion extending from a second side of the housing 102. The housing 102 includes an outer surface 103. The outer surface 103 of the housing 102 is illustrated in dashed lines. The outer surface 103 is an external surface of the housing 102 of the head-mounted device 100.

In the illustration shown in FIG. 1, a shielding material 112 is applied to the housing 102 as a first step in a process to determine the placement of electrostatic discharge shielding on the head-mounted device 100. Similarly, a shielding material 120 is applied to the headband 110, as the headband 110 can be an area of high electrostatic discharge. In various implementations, the shielding material 112 covers the entirety of the outer surface 103 of the housing 102 such that the housing 102 is completely enclosed by the shielding material 112. In some implementations, the shielding material 120 covers the entirety of the headband 110 such that the headband 110 is completely enclosed by the shielding material 120.

As discussed in greater detail herein, portions of the shielding material 112 and the shielding material 120 can be removed from areas of the head-mounted device 100 to check for ESD failures. Successively larger amounts of the shielding material 112 and/or the shielding material 120 may be removed from the head-mounted device 100 so long as an ESD failure is not detected. As incremental portions of the shielding material 112 and/or the shielding material 120 are removed from the head-mounted device 100, an electrical charge is applied to the head-mounted device 100 and assessment for an ESD failure is performed.

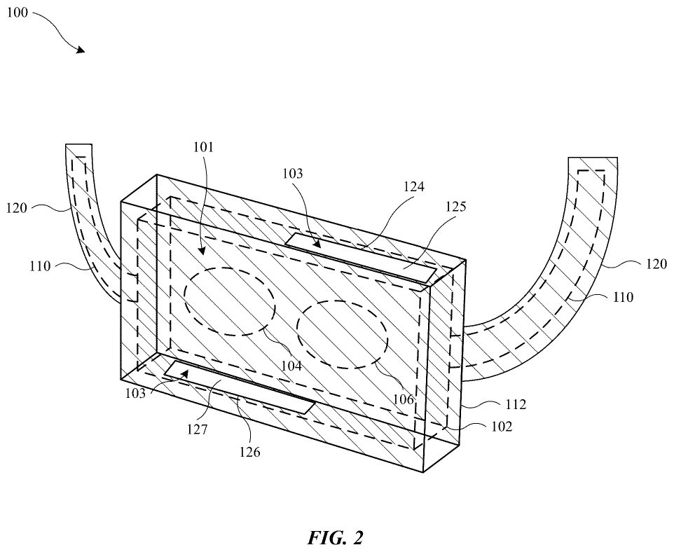

As shown in FIG. 2, a first portion 124 of the shielding material 112 is removed from the housing 102. Removal of the first portion 124 of the shielding material 112 from the housing 102 reveals a first area 125 of the outer surface 103 of the housing 102. With continuing reference to FIG. 2, in some implementations, a second portion 126 of the shielding material 112 is removed from the housing 102. Removal of the second portion 126 of the shielding material 112 from the housing 102 reveals a second area 127 of the outer surface 103 of the housing 102. Removal of the second portion 126 of the shielding material 112 may be or occur subsequent to removal of the first portion 124 of the shielding material 112 and after testing the head-mounted device 100 for an ESD failure.

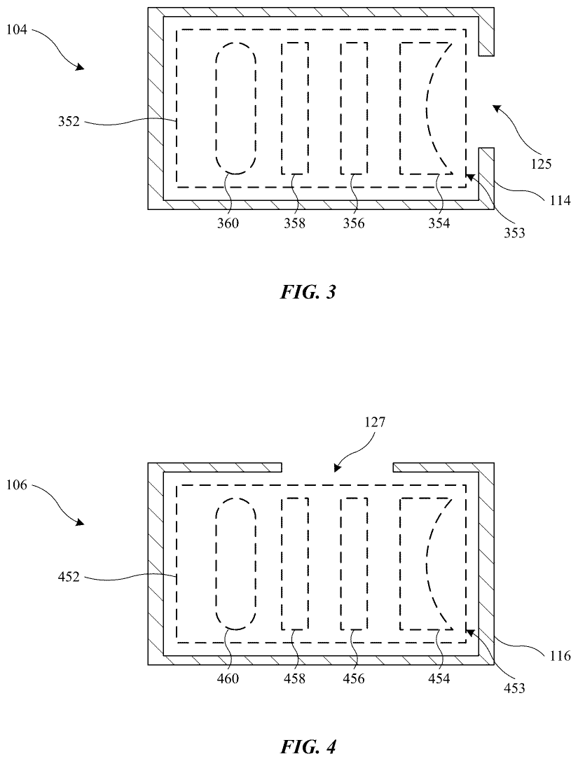

FIG. 3 is a schematic exploded cross-sectional view illustration of the first optical module 104 of the head-mounted device 100. FIG. 4 is a schematic exploded cross-sectional view illustration of the second optical module 106 of the head-mounted device 100. The first optical module 104 and the second optical module 106 include components that deliver display output to the user's eyes.

As shown in FIG. 3, the first optical module 104 includes a first housing 352. The first housing 352 encloses a lens 354, a first display 356, an optical module control board 358, and a fan assembly 360. The lens 354 is configured to direct light emitted from the first display 356 such that the image generated by the first display 356 can be easily viewed by the user. The first display 356 is configured to display user-desired content such as an image or progression of images. The optical module control board 358 includes various components including a controller that includes one or more processors. The optical module control board 358 is coupled with the first display 356 and is configured to control the first display 356.

Operating states of the optical module control board 358 may be monitored to identify circumstances that have been identified as corresponding to an electrostatic discharge failure. For example, a bit flip is a circumstance that can be monitored to determine if an electrostatic discharge failure has occurred. A bit flip is an inadvertent change of state of a bit that is different from its initial state. For example, if a bit changes from 0 to 1 or vice-versa accidentally, the event is called a bit flip.

To determine an amount and placement of ESD shielding material on the head-mounted device 100, in some implementations, the shielding material 114 is applied around an outer surface 353 of the first housing 352 of the first optical module 104. In various implementations, a portion of the shielding material 114 can be removed from the first area 125 of the head-mounted device 100 that includes an area on the outer surface 353 of the first housing 352. Removal of the portion of the shielding material 114 from the first area 125 of the head-mounted device 100 exposes the first area 125 of the outer surface 353 of the first housing 352.

As shown in FIG. 4, the second optical module 106 includes a second housing 452. The second housing 452 encloses a lens 454, a second display 456, an optical module control board 458, and a fan assembly 460. The lens 454 is configured to direct light emitted from the second display 456 such that the image generated by the second display 456 can be easily viewed by the user. The second display 456 is configured to display user-desired content such as an image or progression of images. The optical module control board 458 includes various components including a controller that includes one or more processors. The optical module control board 458 is coupled with the second display 456 and is configured to control the second display 456. Operating states of the optical module control board 458 may be monitored to identify circumstances that have been identified as corresponding to an electrostatic discharge failure. For example, a bit flip is one of those circumstances that can be monitored to determine if an electrostatic discharge failure has occurred.

During an ESD test, as discussed herein, an electrical charge is applied to the head-mounted device 100 with the first area 125 exposed and an assessment is performed to check for an ESD failure. If no failure is detected, a second portion of the shielding material 114, or a portion of the shielding material 116 or the shielding material 112 may be removed from a second area 127 of the head-mounted device 100, as shown in FIG. 4. A subsequent ESD test is performed in which the electrical charge is again applied to the head-mounted device 100 and a second assessment is performed to check for an ESD failure.

The ESD failure could be detected by monitoring a display output of the head-mounted device 100. A display output is one or more images that are output to a display component of each of the first optical module 104 and the second optical module 106, such as the display 356 or the display 456. The display output is viewable to the user via the first optical module 104 and/or the second optical module 106. In some implementations, a display failure is observed when the display 356 outputs an unexpected white or striped display output. In some implementations, an ESD failure is observed when a bit flip is detected.

FIG. 5 is a schematic rear-view illustration of a head-mounted device 500. The head-mounted device 500 includes a housing 502. The housing 502 includes an outer surface 503 which is an external surface of the head-mounted device 500. A user-facing surface 501 of the head-mounted device 500 is also illustrated in FIG. 5. A first optical module 504 and a second optical module 506 are each coupled to the housing 502 and extend from the user-facing surface 501. The first optical module 504 and the second optical module 506 include components similar to those discussed with respect to the first optical module 104 and the second optical module 106 shown in FIGS. 3 and 4. The first optical module 504 includes a first lens 505 with a first lens area 515. The second optical module 506 includes a second lens 507 with a second lens area 517.

For the purpose of determining an amount and placement of ESD shielding material on the head-mounted device 500, a shielding material 512 is applied to the head-mounted device 500 such that the shielding material 512 covers the outer surface 503. In the implementation illustrated in FIG. 5, the shielding material 512 covers the entirety of the outer surface 503 of the housing 502. FIG. 5 also illustrates that a shielding material 514 is applied to the first optical module 504 and a shielding material 516 is applied to the second optical module 506. FIG. 5 further illustrates that a first portion of the shielding material 514 is removed from a first area 524 of the head-mounted device 500 to conduct an ESD test. Specifically, the first portion of the shielding material 514 is removed from the first optical module 504 to reveal the first area 524 of the first optical module 504. In some implementations, removal of the shielding material 514 from the first area 524 reveals a portion of the first lens area 515 of the first optical module 504.

FIG. 5 also illustrates that a first portion of the shielding material 516 is removed from a first area 526 of the second optical module 506 of the head-mounted device 500 during ESD testing. Specifically, the first portion of the shielding material 516 is removed from the first area 526 of the second optical module 506 to reveal a portion of the second lens area 517 of the second optical module 506. The head-mounted device 500 can be tested for ESD failure after revealing the portion of the first lens area 515 of the first optical module 504 and the portion of the second lens area 517 of the second optical module 506.

As discussed in greater detail herein, if the ESD testing performed with portions of the first lens area 515 and the second lens area 517 revealed indicates an ESD failure, such as a display failure, the shielding material 514 can be replaced over the first area 524 and the shielding material 516 can be replaced over the first area 526. A portion of the shielding material 512, the shielding material 514, and/or the shielding material 516 can then be removed from another area of the head-mounted device 500 and further ESD testing performed to test for an ESD failure. If the ESD testing performed with the first area 524 and the first area 526 revealed does not indicate an ESD failure, then an iterative progression of a larger portion of the shielding material 514 and a larger portion of the shielding material 516 can be removed from areas adjacent to the first area 524 and the first area 526, respectively. Successive removal of portions of the shielding material 512, the shielding material 514, and/or the shielding material 516 from the same area or new areas of the head-mounted device 500 may be performed as long as no ESD failures are detected.

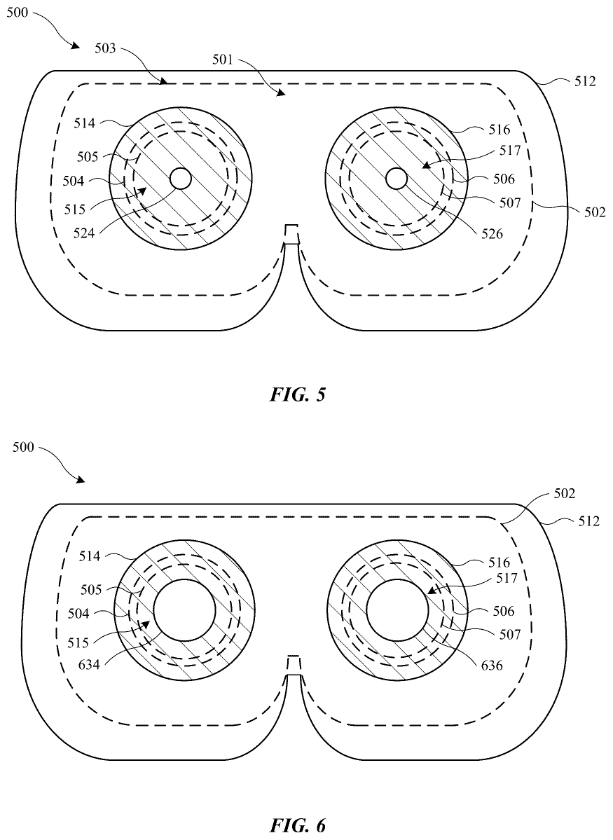

FIG. 6 is a schematic rear-view illustration of the head-mounted device 500 of FIG. 5, with a second, larger opening in the shielding material 514 covering the first optical module 504 and a second, larger opening in the shielding material 516 covering the second optical module 506. In response to successful ESD testing of the head-mounted device 500 shown in FIG. 5 (that is, no ESD failures were detected when the first area 524 of the first optical module 504 and the first area 526 of the second optical module 506 were uncovered), a larger portion of the shielding material 514 and/or the shielding material 516 may be removed from the head-mounted device 500. For example, a larger portion of the shielding material 514 may be removed from the first optical module 504 such that a second area 634 of the first optical module 504 is uncovered, exposing a larger area of the first lens area 515. The second area 634 of FIG. 6 is larger than the first area 524 of FIG. 5. Similarly, a larger portion of the shielding material 516 may be removed from the second optical module 506 such that a second area 636 of the second optical module 506 is uncovered, exposing a larger area of the second lens area 517. The second area 636 of FIG. 6 is larger than the first area 526 of FIG. 5.

ESD testing is performed with the second area 634 and the second area 636 uncovered to further refine the amount and placement of ESD shielding material on the head-mounted device 500. An electrical charge is applied to the head-mounted device 500 and coupling paths associated with an electrostatic discharge failure are assessed. If an ESD failure is detected upon occurrence of a bit flip or for example, observing a display failure such as a color change, white area, or striping pattern, this indicates that the portion of the shielding material 512, the shielding material 514, and/or the shielding material 516 that has been removed from the head-mounted device 500 corresponds to a feature of the head-mounted device 500 that is sensitive to electrostatic discharge, and/or corresponds to a portion of the head-mounted device 500 by which electrostatic charge is conducted to such as sensitive component. Accordingly, such a failure indicates that a portion of the shielding material 512, the shielding material 514, and/or the shielding material 516 should be present in that area or areas as part of the final shielding design for the head-mounted device 500. Thus, all or a portion of the shielding material 514 and/or the shielding material 516 can be replaced on the first optical module 504 and/or the second optical module 506, respectively, for the purpose of conducting further testing in which different portions of the shielding material 514 or the shielding material 516 is removed.

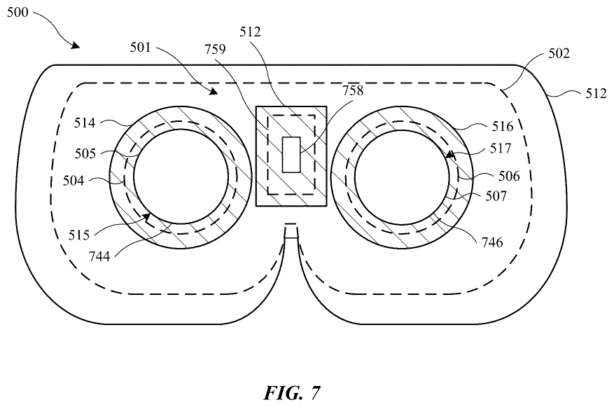

If no ESD failure is detected, an additional portion of the shielding material 512, the shielding material 514, and/or the shielding material 516 can be removed from the head-mounted device 500, as shown in FIG. 7. FIG. 7 is a schematic rear-view illustration of the head-mounted device 500 of FIG. 5 with a larger portion of the shielding material 514 removed from the first optical module 504 such that a third area 744 of the first optical module 504 is uncovered, exposing more of the first lens area 515 of the first optical module 504. Similarly, a larger portion of the shielding material 516 is removed from the second optical module such that a third area 746 of the second optical module 506 is uncovered, exposing more of the second lens area 517 of the second optical module 506.

In response to successful ESD testing of the head-mounted device 500 shown in FIG. 6 (that is, no ESD failures were detected when the second area 634 of the first optical module 504 and the second area 636 of the second optical module 506 were uncovered), a larger portion of the shielding material 514 and the shielding material 516 may be removed from the head-mounted device 500. For example, a larger portion of the shielding material 514 may be removed from the first optical module 504 such that the entirety of the first lens area 515 (e.g., a first lens surface) of the first optical module 504 is uncovered. Similarly, a larger portion of the shielding material 516 may be removed from the second optical module 506 such that the entirety of the second lens area 517 (e.g., a second lens surface) of the second optical module 506 is uncovered.

ESD testing can be conducted on the head-mounted device 500 shown in FIG. 7 to determine optimal placement of the shielding material 512, the shielding material 514, and the shielding material 516. An electrical charge is applied to the head-mounted device 500. The head-mounted device 500 is assessed for an ESD failure, including assessment of the head-mounted device 500 for coupling paths associated with an ESD failure. If an ESD failure is detected, at least a portion of the shielding material 514 can be replaced on the first optical module 504. Similarly, at least a portion of the shielding material 516 can be replaced on the second optical module 506.

If no ESD failure is detected, or, alternatively, if an ESD failure is detected when a portion of the shielding material 514 is removed from the first optical module 504 and when a portion of the shielding material 516 is removed from the second optical module 506, another portion of the shielding material 512, another portion of the shielding material 514, and/or another portion of the shielding material 516 can be removed another area of the head-mounted device 500.

With continued reference to FIG. 7, a portion of the shielding material 512 that covers the housing 502 of the head-mounted device 500 may be removed from the user-facing surface 501. A portion of the shielding material 512 is removed from the housing 502 to expose a portion of the user-facing surface 501 of the housing 502. As shown in FIG. 7, an opening 758 is formed in the shielding material 512 to expose a portion of the user-facing surface 501 of the housing 502. In some implementations, the opening 758 exposes at least a portion of a fan or vent opening 759 in the housing 502.

As discussed with respect to the gradually enlarged openings in the shielding material 514 that covers the first optical module 504 and the shielding material 516 that covers the second optical module 506 of the head-mounted device 500, the opening 758 can be gradually enlarged when application of an electrical charge to the head-mounted device 500 does not result in an ESD failure. A second (or third, fourth, or fifth) assessment of the head-mounted device 500 for coupling paths associated with an electrostatic discharge failure may be performed each time a portion of the shielding material 512, the shielding material 514, and/or the shielding material 516 is removed from the head-mounted device 500.

In some implementations, portions of the shielding material 512 can be removed from various areas of the housing 502, such as over the fan or vent opening 759, at the same time as shielding material 514 is removed from the first optical module 504 and shielding material 516 is removed from the second optical module 506. In other implementations, the first optical module 504 may remain fully shielded or covered by the shielding material 514 and the second optical module 506 may remain fully shielded or covered by the shielding material 516 while the opening 758 is gradually enlarged during ESD testing until a failure condition is detected. Once an ESD failure is detected, a minimal amount of shielding of the head-mounted device 500 is determined (that is, removing further shielding will not result in a passing assessment of electrostatic discharge).

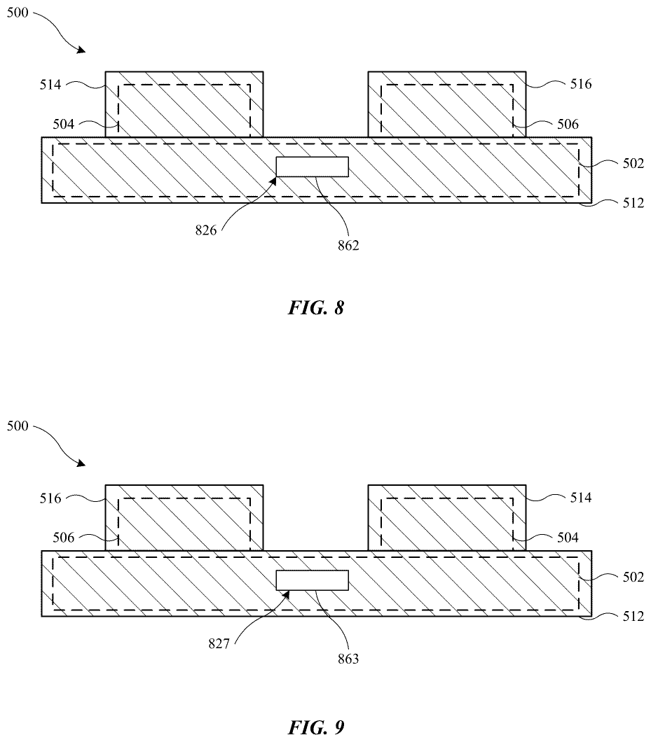

FIG. 8 is a schematic top-view illustration of the head-mounted device 500 of FIG. 5. In this illustration, the housing 502 is covered with the shielding material 512, the first optical module 504 is covered with the shielding material 514, and the second optical module 106 is covered with the shielding material 516. In various implementations, the shielding material 512, the shielding material 514, and the shielding material 516 are separate pieces (that is, they are not connected or contiguous). As shown in FIG. 8, a portion of the shielding material 512 is removed from the housing 502 to expose a first fan opening 862 defined by the housing 502. The first fan opening 862 is defined by the housing 502 on a first side of the housing 502.

FIG. 9 is a schematic underside-view illustration of the head-mounted device 500 of FIG. 5. In this illustration, similar to FIG. 8, the housing 502 is covered with the shielding material 512, the first optical module 504 is covered with the shielding material 514, and the second optical module 106 is covered with the shielding material 516. As shown in FIG. 9, a portion of the shielding material 512 is removed from the housing 502 to expose a second fan opening 863 defined by the housing 502. The second fan opening 863 is defined by the housing 502 on a second side of the housing 502. In various implementations, a first portion of the shielding material 512 is removed from a first area 826 of the housing 502 of the head-mounted device 500, such as over the first fan opening 862, and a second portion of the shielding material 512 is removed from a second area 827 of the housing 502 of the head-mounted device 500, such as over the second fan opening 863.

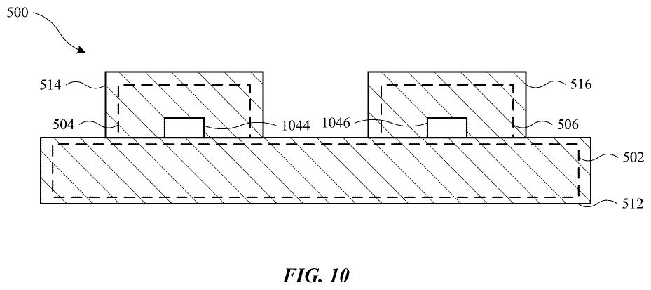

FIG. 10 is a schematic top-view illustration of the head-mounted device 500 of FIG. 5 with a first opening 1044 in the shielding material 514 covering the first optical module 504 and a second opening 1046 in the shielding material 516 covering the second optical module 506. In this implementation, a first portion of shielding material 514 is removed from the head-mounted device 500 over the first opening 1044 on an upper-facing surface of the first optical module 504. A second portion of shielding material 516 is removed from the head-mounted device 500 over the second opening 1046 on an upper-facing surface of the second optical module 506.

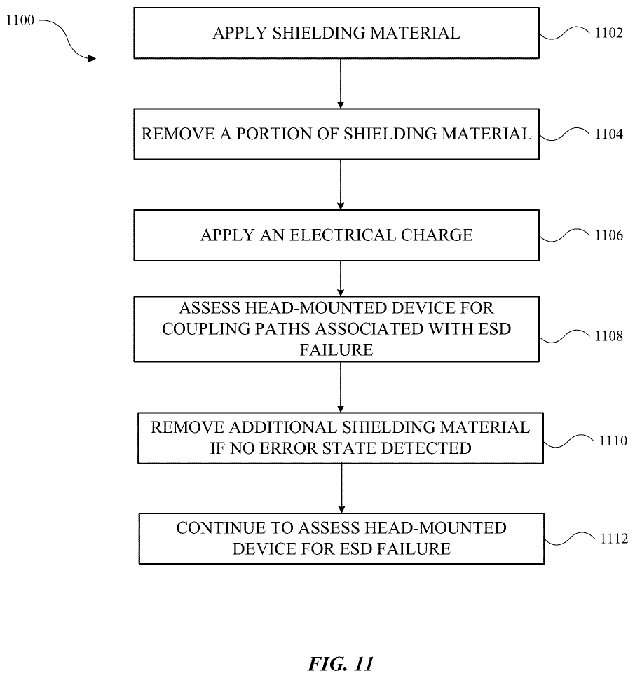

FIG. 11 is a flowchart diagram of a method 1100 for electrostatic discharge testing of the head-mounted device 100, according to an implementation. The method 1100 may be implemented with the head-mounted device 100 or the head-mounted device 500 discussed herein. The method 1100 may be performed in another order than the steps listed in FIG. 11.

At step 1102, a shielding material, such as the shielding material 112, is applied to the head-mounted device 100. The shielding material 112 is applied to head-mounted device 100 such that the shielding material 112 covers the outer surface 103 of the housing 102. Additionally, the shielding material 120 is applied to cover the headband 110. In various implementations, the shielding material 112 and the shielding material 120 are formed from a conductive flexible material that can be wrapped around the curves, corners, and other outer surface shapes of the head-mounted device 100. As one example, the shielding material 112 and the shielding material 120 may be a metallic foil (e.g., copper, aluminum, etc.). As another example, the shielding material 112 and the shielding material 120 may be an adhesive tape that has a conductive layer, is formed with embedded conductive fibers, is treated with a conductive coating, or otherwise defines a thin, flexible, conductive structure that can disperse electrostatic charge over a large area, and/or to a ground. The shielding material 112 and the shielding material 120 are configured to shield the head-mounted device 100 from electrostatic discharge when an electrical charge is applied to the head-mounted device 100. The shielding material 112 and the shielding material 120 are also flexible and may be easily removed from selected areas of the head-mounted device 100.

Next, at step 1104, a first portion 124 of the shielding material 112 is removed from a first area 125 of the head-mounted device 100. For example, removing the first portion 124 of the shielding material 112 from the first area 125 of the head-mounted device 100 or the head-mounted device 500 includes removing a portion of the shielding material 112 from the housing 102 or removing a portion of the shielding material 512 from the housing 502 to expose a fan opening, such as the first fan opening 862 defined by the housing 502 and shown in FIG. 8. In another example, removing the first portion 124 of the shielding material 112 from the first area 125 of the head-mounted device 100 includes removing a portion of the shielding material 112 to expose a portion of the housing 102 between the first optical module 104 and the second optical module 106. As shown in FIG. 7, the shielding material 512 is removed from the housing 502 to form an opening 758 in the shielding material 512 to expose a portion of the user-facing surface 501 of the housing 502.

Following removal of a portion of the shielding material 112 from the head-mounted device 100, an electrical charge is applied to the head-mounted device 100, as shown at step 1106. The electrical charge may be applied by contact between the head-mounted device 100 and a contact discharge component of an electrostatic discharge simulator device. An electrostatic discharge device is a conventional testing device that that is configured to generate controlled electrical pulses to test vulnerability of an electronic device, such as the head-mounted device 100, to electrostatic discharge events. The electrical charge that is applied to the head-mounted device 100 by the electrostatic discharge device may by an ESD pulse that includes both current and voltage components with a waveform criteria verified for compliance to a particular standard.

After applying the electrical charge, the method 1100 includes the step of assessing the head-mounted device 100 for coupling paths associated with an electrostatic discharge failure, as shown at step 1108. Assessing the head-mounted device 100 for coupling paths may include monitoring a component of the head-mounted device 100 to identify an error state induced by application of the electrical charge to the head-mounted device 100. The coupling paths indicative of an ESD failure event may cause the display of the optical module, such as the display 356 of the first optical module 104 shown in FIG. 3, to display images that are not consistent with the images that are intended to by displayed by the display 356, such as a fully black image, a fully white image, or striped images.

If no error state is detected or identified, the method 1100 proceeds to step 1110. At step 1110, in response to determining that the electrostatic discharge failure has not been detected, a second portion 126 of the shielding material 112 is removed from a second area 127 of the head-mounted device 100. In some implementations, removing the first portion 124 of the shielding material 112 from the head-mounted device 100 or the head-mounted device 500 includes exposing a first fan opening, such as the first fan opening 862, defined by the housing 502 on a first side of the housing 502. After assessing the head-mounted device 100 or the head-mounted device 500 for coupling paths associated with an ESD failure after exposing the first fan opening 862, if no ESD failure is detected, removing a second portion 126 of the shielding material 112 from the head-mounted device 100 includes exposing a second fan opening, such as the second fan opening 863, defined by the housing 502 on a second side of the housing 502, as shown in FIG. 9.

The method 1100 continues at step 1112, with performing a second assessment of the head-mounted device 100 for coupling paths associated with an electrostatic discharge failure with the first portion 124 and the second portion 126 of the shielding material 112 removed from the head-mounted device 100. In various implementations, the method 1100 continues with removal of successively more of the shielding material (such as, for example, shielding material 514 covering the first optical module 504, shielding material 516 covering the second optical module 506, and shielding material 512 covering the user-facing surface 501 of the housing 502 between the first optical module 504 and the second optical module 506) until an ESD failure is detected after application of the electrical charge.

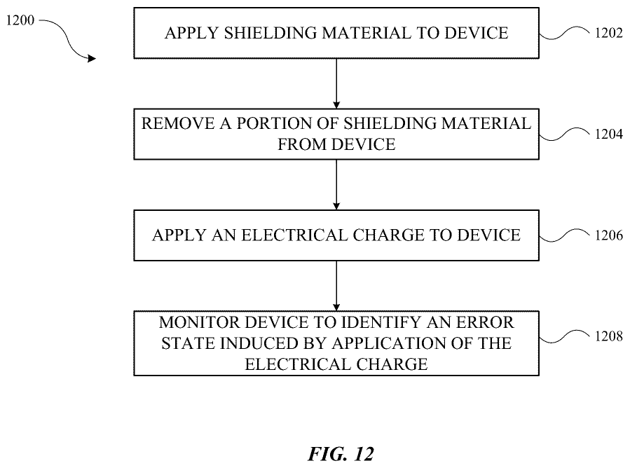

FIG. 12 is a flowchart of a method 1200 for electrostatic discharge testing of the head-mounted device 100 or the head-mounted device 500, according to another implementation. In this implementation, the head-mounted device 100 includes the first optical module 104 having the first display 356 and the second optical module 106 having the second display 456. The first optical module 104 is enclosed within the first housing 352. The second optical module 106 is enclosed with the second housing 452. The method 1200 may be implemented with the head-mounted device 100 or the head-mounted device 500 discussed herein. The method 1200 may be performed in another order than the steps listed in FIG. 12.

First, at step 1202, the shielding material 114 is applied around an outer surface 353 of the first housing 352 enclosing the first optical module 104 and around the outer surface 453 of the second housing 452 enclosing the second optical module 106.

Next, at step 1204, the method 1200 continues with removing a first portion of the shielding material 114 from a first area 125 of the head-mounted device 100. As shown in FIG. 2, the first area 125 of the head-mounted device 100 may be a portion of the shielding material 112 applied to and covering the housing 102. As shown in FIG. 5, removal of the shielding material 514 from the first area 524 reveals a portion of the first lens area 515 of the first optical module 504. In some implementations, removal of the shielding material 516 from the first area 526 of the second optical module 506 reveals a portion of the second lens area 517 of the second optical module 506.

The method 1200 continues at step 1206 with applying an electrical charge to the head-mounted device 100 or the head-mounted device 500. The electrical charge may be applied using any known method of applying an electrical charge to a device to assess electrostatic discharge including air discharge and contact discharge.

At step 1208, the method 1200 continues with monitoring a component of the head-mounted device 100 or the head-mounted device 500 to identify an error state induced by application of the electrical charge to the head-mounted device 100 or the head-mounted device 500. In some implementations, monitoring the component of the head-mounted device 100 or the head-mounted device 500 includes monitoring the head-mounted device 100 or the head-mounted device 500 for a bit flip. For example, a memory or other component of the optical module control board 358 of the first optical module 104 is monitored for occurrence of a bit flip after application of the electrical charge. In some implementations, monitoring the component of the head-mounted device 100 includes monitoring the first display 356 of the first optical module 104 for a display anomaly or failure, such as a black/white output or striped output.

When a bit flip is detected, the method 1200 can include an additional step of replacing the first portion of the shielding material 112 on the head-mounted device 100 at the first area 125 and removing a second portion of the shielding material 112 from a second area 127 of the head-mounted device 100. The removal of the second portion of the shielding material 112 from the second area 127 of the head-mounted device 100 can include removing the shielding material 112 to expose a portion of the user-facing surface 101 of the housing 102. In some implementations, removal of the second portion of the shielding material 112 from the second area 127 of the head-mounted device 100 can include removing the shielding material 512 from the first fan opening 862 or from the second fan opening 863.

The method 1200 may include repetition of step 1206, wherein the electrical charge is applied to the head-mounted device 100 and of step 1208, continuing to monitor the component of the head-mounted device 100 with the second portion of the shielding material 112 removed from the second area 127 of the head-mounted device 100.

The method 1200 can be repeated with a portion of the shielding material 112 replaced on the head-mounted device 100 if an ESD failure is detected. The method 1200 can also be repeated by removing more of the shielding material 112 from the head-mounted device 100, such as the successive removal of larger portions of the shielding material 514 from the first optical module 504 and portions of the shielding material 516 from the second optical module 506, as shown in FIGS. 5-7. After each removal of a respective portion of the shielding material 112, the shielding material 512, the shielding material 514, and/or the shielding material 516, an electrical charge is applied to the head-mounted device 100 or the head-mounted device 500 and the head-mounted device 100 or the head-mounted device 500 is monitored for a display failure or anomaly, coupling paths associated with an ESD failure, and/or a bit flip. One or more iterations of removing an additional portion of the shielding material 112 from the head-mounted device 100 or the head-mounted device 500 may be performed, with an assessment of the head-mounted device 100 or the head-mounted device 500 for an ESD failure performed after each removal of shielding material 112, the shielding material 512, the shielding material 514, and/or the shielding material 516.

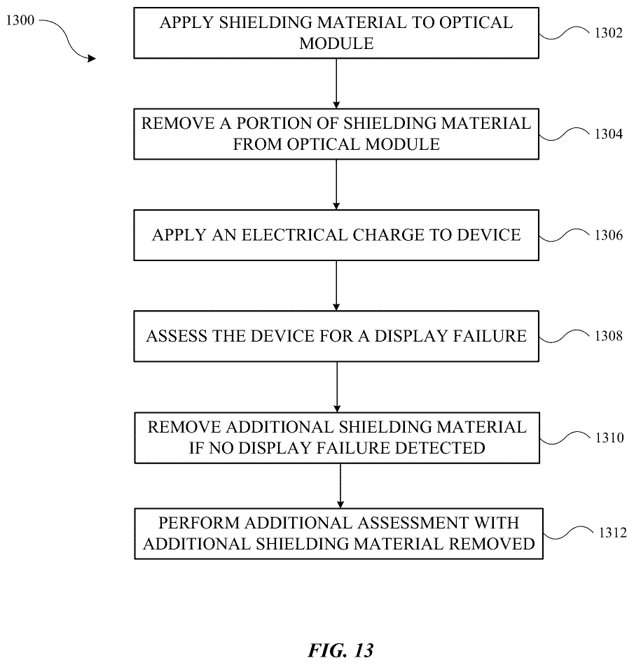

FIG. 13 is a flowchart of a method 1300 for determining placement of electrostatic discharge shielding on a head-mounted device 100 that includes a first optical module 104 and a second optical module 106, according to an implementation. The method 1300 may also be performed on the head-mounted device 500 that includes the first optical module 504 and the second optical module 506. The method 1300 may be implemented with the head-mounted device 100 or the head-mounted device 500 discussed herein. The method 1300 may be performed in another order than the steps listed in FIG. 13.

The method 1300 begins at step 1302 with applying the shielding material 114 to an outer surface 353 of the first optical module 104 and an outer surface 453 of the second optical module 106. As shown in FIGS. 2, 3, and 4, the shielding material 114 is applied around the outer surface 353 of the first housing 352 of the first optical module 104. The shielding material 116 is applied around the outer surface 453 of the second housing 452 of the second optical module 106.

At step 1304, the method 1300 continues with removing a first portion of the shielding material 114 from a first area 125 of the first optical module 104 such that a first portion of the first optical module 104 is not covered by the shielding material 114. As shown in FIGS. 2 and 3, a first portion of the shielding material 114 is removed from the first area 125 of the first optical module 104 to reveal a first portion 124 of the first optical module 104, such as proximate to the first display 356 of the first optical module 104. Additionally, in some implementations, the method 1300 includes removing a second portion of the shielding material 116 from a second area 127 of the second optical module 106 to reveal a second portion 126 of the second optical module 106, such as proximate to the second display 456 of the second optical module 106. In some implementations, as shown in FIG. 5, a first portion of the shielding material 514 is removed from the first area 524 of the first optical module 504 to reveal a portion of the first lens area 515 of the first optical module 504 and a first portion of the shielding material 516 is removed from the first area 526 of the second optical module 506 to reveal a portion of the second lens area 517.

Next, at step 1306, the method 1300 continues with applying an electrical charge to the head-mounted device 100 or the head-mounted device 500. The electrical charge may be applied using any known method of applying an electrical charge to a device to assess electrostatic discharge including air discharge and contact discharge.

Following the application of the electrical charge to the head-mounted device 100 or the head-mounted device 500, the method 1300 continues at step 1308 with determining whether a display failure is detected. Determining whether the display failure is detected includes, in some implementations, assessing a display status of the first optical module 104 or the first optical module 504 and assessing a display status of the second optical module 106 or the second optical module 506. Assessing the display status of the first optical module 104 or the first optical module 504 includes determining whether the images output by the first optical module 104 or the first optical module 504 are consistent with the images that are intended to be displayed by first optical module 104 or the first optical module 504 (e.g., whether the first optical module 104 or the first optical module 504 is operating as intended). Assessing the display status of the first optical module 104 or the first optical module 504 may include observing the display of the first optical module 104 or the first optical module 504 for a display anomaly such as output of an all-white image by the first display 356 or output of a striped image by the first display 356. Similarly, assessing the display status of the second optical module 106 or the second optical module 506 may include observing the second display 456 of the second optical module 106 or the second optical module 506 for the display anomaly.

In response to determining that the display failure is not detected, the method 1300 proceeds with step 1310. At step 1310, the method 1300 continues with removing a larger portion of the shielding material 114 from the first optical module 104 or a larger portion of the shielding material 514 from the first optical module 504 such that a second portion of the first optical module 104 is not covered by the shielding material 114 or a second portion of the first optical module 504 is not covered by the shielding material 514. Step 1310 may also include removing a larger portion of the shielding material 116 from the second optical module 106 or removing a larger portion of the shielding material 516 from the second optical module 506 such that a second portion of the second optical module 106 is not covered by the shielding material 116 or a second portion of the second optical module 506 is not covered by the shielding material 516. For example, as shown in FIG. 6, a third or larger portion of the shielding material 514 is removed from the first optical module 104 such that the second area 634 of the first optical module 104 is uncovered. The second area 634 is larger than the first area 524. Similarly, a fourth portion of the shielding material 516 is removed from the second optical module 506 such that the second area 636 of the second optical module 506 is uncovered. The second area 636 is larger than the first area 526.

With the second area 634 and the second area 636 uncovered, the method 1300 proceeds to step 1312, wherein the electrical charge is applied to the head-mounted device 500 and additional assessments are performed on the head-mounted device 500 for ESD failure. For example, the method 1300 includes performing a second determination of whether the display failure is detected subsequent to removing the third portion of the shielding material 514 from the first optical module 504 and removing the fourth portion of the shielding material 516 from the second optical module 506, and, if the display failure is not detected, removing a fifth portion of the shielding material 514 from the first optical module 504 such that a surface of the first lens area 515 of the first optical module 504 is not covered with the shielding material 514. One or more iterations of removing an additional portion of the shielding material 514 and/or the shielding material 516 from the head-mounted device 500 are performed until the display failure is detected. The additional portions of shielding material 514 and/or the shielding material 516 can be removed to uncover the first fan opening 862 or the second fan opening 863, a greater portion of the first display 356 or the second display 456, the lens 354 or the lens 454, or other outer surfaces of the housing 502, as long as no ESD failure is detected.

A physical environment refers to a physical world that people can sense and/or interact with without aid of electronic systems. Physical environments, such as a physical park, include physical articles, such as physical trees, physical buildings, and physical people. People can directly sense and/or interact with the physical environment, such as through sight, touch, hearing, taste, and smell.

In contrast, a computer-generated reality (CGR) environment refers to a wholly or partially simulated environment that people sense and/or interact with via an electronic system. In CGR, a subset of a person's physical motions, or representations thereof, are tracked, and, in response, one or more characteristics of one or more virtual objects simulated in the CGR environment are adjusted in a manner that comports with at least one law of physics. For example, a CGR system may detect a person's head turning and, in response, adjust graphical content and an acoustic field presented to the person in a manner similar to how such views and sounds would change in a physical environment. In some situations (e.g., for accessibility reasons), adjustments to characteristic(s) of virtual object(s) in a CGR environment may be made in response to representations of physical motions (e.g., vocal commands).

A person may sense and/or interact with a CGR object using any one of their senses, including sight, sound, touch, taste, and smell. For example, a person may sense and/or interact with audio objects that create three-dimensional or spatial audio environment that provides the perception of point audio sources in three-dimensional space. In another example, audio objects may enable audio transparency, which selectively incorporates ambient sounds from the physical environment with or without computer-generated audio. In some CGR environments, a person may sense and/or interact only with audio objects.

Examples of CGR include virtual reality and mixed reality.

A virtual reality (VR) environment refers to a simulated environment that is designed to be based entirely on computer-generated sensory inputs for one or more senses. A VR environment comprises a plurality of virtual objects with which a person may sense and/or interact. For example, computer-generated imagery of trees, buildings, and avatars representing people are examples of virtual objects. A person may sense and/or interact with virtual objects in the VR environment through a simulation of the person's presence within the computer-generated environment, and/or through a simulation of a subset of the person's physical movements within the computer-generated environment.

In contrast to a VR environment, which is designed to be based entirely on computer-generated sensory inputs, a mixed reality (MR) environment refers to a simulated environment that is designed to incorporate sensory inputs from the physical environment, or a representation thereof, in addition to including computer-generated sensory inputs (e.g., virtual objects). On a virtuality continuum, a mixed reality environment is anywhere between, but not including, a wholly physical environment at one end and virtual reality environment at the other end.

In some MR environments, computer-generated sensory inputs may respond to changes in sensory inputs from the physical environment. Also, some electronic systems for presenting an MR environment may track location and/or orientation with respect to the physical environment to enable virtual objects to interact with real objects (that is, physical articles from the physical environment or representations thereof). For example, a system may account for movements so that a virtual tree appears stationary with respect to the physical ground.

Examples of mixed realities include augmented reality and augmented virtuality.

An augmented reality (AR) environment refers to a simulated environment in which one or more virtual objects are superimposed over a physical environment, or a representation thereof. For example, an electronic system for presenting an AR environment may have a transparent or translucent display through which a person may directly view the physical environment. The system may be configured to present virtual objects on the transparent or translucent display, so that a person, using the system, perceives the virtual objects superimposed over the physical environment. Alternatively, a system may have an opaque display and one or more imaging sensors that capture images or video of the physical environment, which are representations of the physical environment. The system composites the images or video with virtual objects and presents the composition on the opaque display. A person, using the system, indirectly views the physical environment by way of the images or video of the physical environment, and perceives the virtual objects superimposed over the physical environment. As used herein, a video of the physical environment shown on an opaque display is called “pass-through video,” meaning a system uses one or more image sensor(s) to capture images of the physical environment and uses those images in presenting the AR environment on the opaque display. Further alternatively, a system may have a projection system that projects virtual objects into the physical environment, for example, as a hologram or on a physical surface, so that a person, using the system, perceives the virtual objects superimposed over the physical environment.

An augmented reality environment also refers to a simulated environment in which a representation of a physical environment is transformed by computer-generated sensory information. For example, in providing pass-through video, a system may transform one or more sensor images to impose a select perspective (e.g., viewpoint) different than the perspective captured by the imaging sensors. As another example, a representation of a physical environment may be transformed by graphically modifying (e.g., enlarging) portions thereof, such that the modified portion may be representative but not photorealistic versions of the originally captured images. As a further example, a representation of a physical environment may be transformed by graphically eliminating or obfuscating portions thereof.

An augmented virtuality (AV) environment refers to a simulated environment in which a virtual or computer-generated environment incorporates one or more sensory inputs from the physical environment. The sensory inputs may be representations of one or more characteristics of the physical environment. For example, an AV park may have virtual trees and virtual buildings, but people with faces photorealistically reproduced from images taken of physical people. As another example, a virtual object may adopt a shape or color of a physical article imaged by one or more imaging sensors. As a further example, a virtual object may adopt shadows consistent with the position of the sun in the physical environment.

There are many different types of electronic systems that enable a person to sense and/or interact with various CGR environments. Examples include head-mounted systems, projection-based systems, heads-up displays (HUDs), vehicle windshields having integrated display capability, windows having integrated display capability, displays formed as lenses designed to be placed on a person's eyes (e.g., similar to contact lenses), headphones/earphones, speaker arrays, input systems (e.g., wearable or handheld controllers with or without haptic feedback), smartphones, tablets, and desktop/laptop computers. A head-mounted system may have one or more speaker(s) and an integrated opaque display. Alternatively, a head-mounted system may be configured to accept an external opaque display (e.g., a smartphone). The head-mounted system may incorporate one or more imaging sensors to capture images or video of the physical environment, and/or one or more microphones to capture audio of the physical environment. Rather than an opaque display, a head-mounted system may have a transparent or translucent display. The transparent or translucent display may have a medium through which light representative of images is directed to a person's eyes. The display may utilize digital light projection, OLEDs, LEDs, uLEDs, liquid crystal on silicon, laser scanning light source, or any combination of these technologies. The medium may be an optical waveguide, a hologram medium, an optical combiner, an optical reflector, or any combination thereof. In one embodiment, the transparent or translucent display may be configured to become opaque selectively. Projection-based systems may employ retinal projection technology that projects graphical images onto a person's retina. Projection systems also may be configured to project virtual objects into the physical environment, for example, as a hologram or on a physical surface.

As described above, one aspect of the present technology is the gathering and use of data available from various sources for use during operation of a head-mounted device. As an example, such data may identify the user and include user-specific settings or preferences. The present disclosure contemplates that in some instances, this gathered data may include personal information data that uniquely identifies or can be used to contact or locate a specific person. Such personal information data can include demographic data, location-based data, telephone numbers, email addresses, twitter ID's, home addresses, data or records relating to a user's health or level of fitness (e.g., vital signs measurements, medication information, exercise information), date of birth, or any other identifying or personal information.

The present disclosure recognizes that the use of such personal information data, in the present technology, can be used to the benefit of users. For example, a user profile may be established that stores user preference related information that allows adjustment of operation of the device according to user preferences. Accordingly, use of such personal information data enhances the user's experience.

The present disclosure contemplates that the entities responsible for the collection, analysis, disclosure, transfer, storage, or other use of such personal information data will comply with well-established privacy policies and/or privacy practices. In particular, such entities should implement and consistently use privacy policies and practices that are generally recognized as meeting or exceeding industry or governmental requirements for maintaining personal information data private and secure. Such policies should be easily accessible by users, and should be updated as the collection and/or use of data changes. Personal information from users should be collected for legitimate and reasonable uses of the entity and not shared or sold outside of those legitimate uses. Further, such collection/sharing should occur after receiving the informed consent of the users. Additionally, such entities should consider taking any needed steps for safeguarding and securing access to such personal information data and ensuring that others with access to the personal information data adhere to their privacy policies and procedures. Further, such entities can subject themselves to evaluation by third parties to certify their adherence to widely accepted privacy policies and practices. In addition, policies and practices should be adapted for the particular types of personal information data being collected and/or accessed and adapted to applicable laws and standards, including jurisdiction-specific considerations. For instance, in the US, collection of or access to certain health data may be governed by federal and/or state laws, such as the Health Insurance Portability and Accountability Act (HIPAA); whereas health data in other countries may be subject to other regulations and policies and should be handled accordingly. Hence different privacy practices should be maintained for different personal data types in each country.

Despite the foregoing, the present disclosure also contemplates embodiments in which users selectively block the use of, or access to, personal information data. That is, the present disclosure contemplates that hardware and/or software elements can be provided to prevent or block access to such personal information data. For example, in the case of storing a user profile, the present technology can be configured to allow users to select to “opt in” or “opt out” of participation in the collection of personal information data during registration for services or anytime thereafter. In another example, users can select not to provide data regarding usage of specific applications. In yet another example, users can select to limit the length of time that application usage data is maintained or entirely prohibit the development of an application usage profile. In addition to providing “opt in” and “opt out” options, the present disclosure contemplates providing notifications relating to the access or use of personal information. For instance, a user may be notified upon downloading an app that their personal information data will be accessed and then reminded again just before personal information data is accessed by the app.

Moreover, it is the intent of the present disclosure that personal information data should be managed and handled in a way to minimize risks of unintentional or unauthorized access or use. Risk can be minimized by limiting the collection of data and deleting data once it is no longer needed. In addition, and when applicable, including in certain health related applications, data de-identification can be used to protect a user's privacy. De-identification may be facilitated, when appropriate, by removing specific identifiers (e.g., date of birth, etc.), controlling the amount or specificity of data stored (e.g., collecting location data at a city level rather than at an address level), controlling how data is stored (e.g., aggregating data across users), and/or other methods.

Therefore, although the present disclosure broadly covers use of personal information data to implement one or more various disclosed embodiments, the present disclosure also contemplates that the various embodiments can also be implemented without the need for accessing such personal information data. That is, the various embodiments of the present technology are not rendered inoperable due to the lack of all or a portion of such personal information data. For example, user preference information may be determined each time the device is used, and without subsequently storing the information or associating with the particular user.

What is claimed is:

1. A method for electrostatic discharge testing of a head-mounted device including a housing and a headband coupled to the housing, the method comprising:
applying a shielding material to the head-mounted device such that the shielding material covers an outer surface of the housing and an outer surface of the headband;
removing a first portion of the shielding material from a first area of the head-mounted device;
applying an electrical charge to the head-mounted device; and
assessing the head-mounted device for coupling paths associated with an electrostatic discharge failure.

2. The method of claim 1, wherein removing the first portion of the shielding material from the first area of the head-mounted device includes removing a portion of the shielding material from the housing to expose a fan opening defined by the housing.

3. The method of claim 1, wherein removing the first portion of the shielding material from the first area of the head-mounted device includes removing a portion of the shielding material to expose a portion of the housing between a first optical module and a second optical module.

4. The method of claim 1, further comprising:
determining that the electrostatic discharge failure has not been detected; and
in response to determining that the electrostatic discharge failure has not been detected, removing a second portion of the shielding material from a second area of the head-mounted device.

5. The method of claim 4, wherein removing the first portion of the shielding material includes exposing a first fan opening defined by the housing on a first side of the housing and removing the second portion of the shielding material includes exposing a second fan opening defined by the housing on a second side of the housing.

6. The method of claim 5, further comprising:
performing a second assessment of the head-mounted device for coupling paths associated with an electrostatic discharge failure with the first portion and the second portion of the shielding material removed from the head-mounted device.

7. A method for electrostatic discharge testing of a head-mounted device including a first optical module having a first display and a second optical module having a second display, the first optical module enclosed within a first housing and the second optical module enclosed within a second housing, the method comprising:
applying a shielding material around an outer surface of the first housing and an outer surface of the second housing;
removing a first portion of the shielding material from a first area of the head-mounted device;
applying an electrical charge to the head-mounted device; and
monitoring a component of the head-mounted device to identify an error state induced by application of the electrical charge to the head-mounted device.

8. The method of claim 7, wherein monitoring the component of the head-mounted device includes monitoring the head-mounted device for a bit flip.

9. The method of claim 8, wherein when the bit flip is detected, the method further comprises replacing the first portion of the shielding material, removing a second portion of the shielding material from a second area of the head-mounted device, applying the electrical charge to the head-mounted device, and continuing to monitor the component of the head-mounted device with the second portion of the shielding material removed from the second area of the head-mounted device.

10. The method of claim 7, wherein removing the first portion of the shielding material from the head-mounted device includes removing a first portion of the shielding material from the first optical module such that a first portion of a display of the first optical module is uncovered.

11. The method of claim 10, wherein monitoring the component of the head-mounted device includes monitoring the display of the first optical module for a display failure.

12. The method of claim 11, further comprising:
determining whether the display failure has occurred; and
in response to determining that the display failure has occurred, replacing the first portion of the shielding material on the head-mounted device.

13. The method of claim 11, further comprising:
determining whether the display failure has occurred; and
in response to determining that the display failure has not occurred, removing a second portion of the shielding material from the first optical module such that a second portion of the display of the first optical module is uncovered, wherein the second portion of the shielding material is larger than the first portion of the shielding material.

14. The method of claim 11, wherein monitoring the display of the first optical module for the display failure includes registering an occurrence of a display anomaly.

15. A method for determining placement of electrostatic discharge shielding on a head-mounted device that includes a first optical module and a second optical module, the method comprising:
applying a shielding material to an outer surface of the first optical module and an outer surface of the second optical module;
removing a first portion of the shielding material from a first area of the first optical module such that a first portion of the first optical module is not covered by the shielding material;
removing a second portion of the shielding material from a first area of the second optical module such that a first portion of the second optical module is not covered by the shielding material;
applying an electrical charge to the head-mounted device; and
determining whether a display failure is detected.

16. The method of claim 15, wherein determining whether the display failure is detected includes assessing a display status of the first optical module and assessing a display status of the second optical module.

17. The method of claim 15, further comprising:
in response to determining that the display failure is not detected, removing a third portion of the shielding material from the first optical module such that a second portion of the first optical module is not covered by the shielding material and removing a fourth portion of the shielding material from the second optical module such that a second portion of the second optical module is not covered by the shielding material.

18. The method of claim 17, further comprising:
performing a second determination of whether the display failure is detected subsequent to removing the third portion of the shielding material from the first optical module and removing the fourth portion of the shielding material from the second optical module, and, if the display failure is not detected, removing a fifth portion of the shielding material from the first optical module such that a surface of a lens area of the first optical module is not covered with the shielding material.

19. The method of claim 15, further comprising:
performing one or more iterations of removing an additional portion of shielding material from the head-mounted device and determining whether the display failure is detected until the display failure is detected.

20. The method of claim 19, wherein the display failure is detected upon occurrence of a bit flip.
